(19) United States
(12) Patent Application Publication
(10) Pub. No.: US 2010/0309602 A1
(43) Pub. Date: Dec. 9, 2010

(54) PRINTED CIRCUIT BOARD AND ELECTROSTATIC DISCHARGE PROTECTION METHOD FOR THE SAME

(75) Inventor: HUNG-YI CHIEN, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/545,035

(22) Filed: Aug. 20, 2009

(30) Foreign Application Priority Data
Jun. 9, 2009 (CN) 200910303083.0

(51) Int. Cl. H05F 3/02; H05K 1/18

(52) U.S. Cl. 361/220; 174/260

(57) ABSTRACT

A printed circuit board (PCB) includes a switch mounted on a signal layer of the PCB. A plurality of grounding copper foils are formed at opposite sides of the switch. A first end of each of the grounding copper foils is adjacent to the switch. The switch includes an electroplated button and a switch component under the electroplated button. An inner surface connected to the switch component of the electroplated button is coated with lacquer.

### BACKGROUND

1. Technical Field

The present disclosure relates to printed circuit boards (PCBs), and particularly to a PCB in a portable electronic device and an electrostatic discharge (ESD) protection method for the PCB.

2. Description of Related Art

In general, electronic products, such as PCBs, are susceptible to damage by ESD during utilization. ESD often occurs when a user touches an electronic component. ESD can result in complete or intermittent failures of the electronic component.

A common means to prevent damage from ESD is to mount ESD protection components, such as rheostats or diodes, adjacent to components needing protection. Electrostatic current is led to ground via the ESD protection components, thereby providing protection. However, many ESD protection components are often necessary to protect all the various parts in a device, which is costly.

### BRIEF DESCRIPTION OF THE DRAWINGS

FIG. 1 is a sketch view of an exemplary embodiment of a printed circuit board including copper foils.

FIG. 2 is a cross-sectional view of FIG. 1, taken along the copper foils.

FIG. 3 is a flowchart of an exemplary embodiment of an electrostatic discharge protection method for the printed circuit board of FIG. 1.

### DETAILED DESCRIPTION

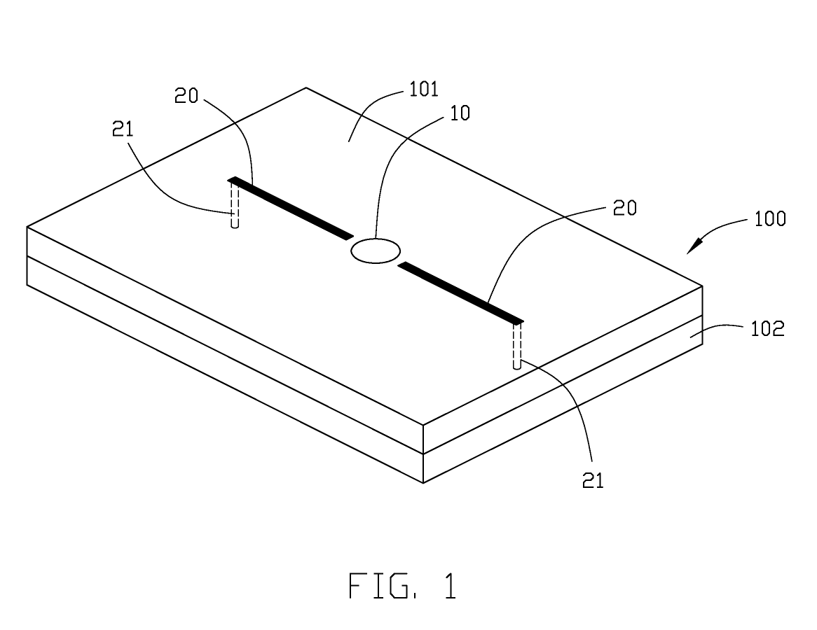

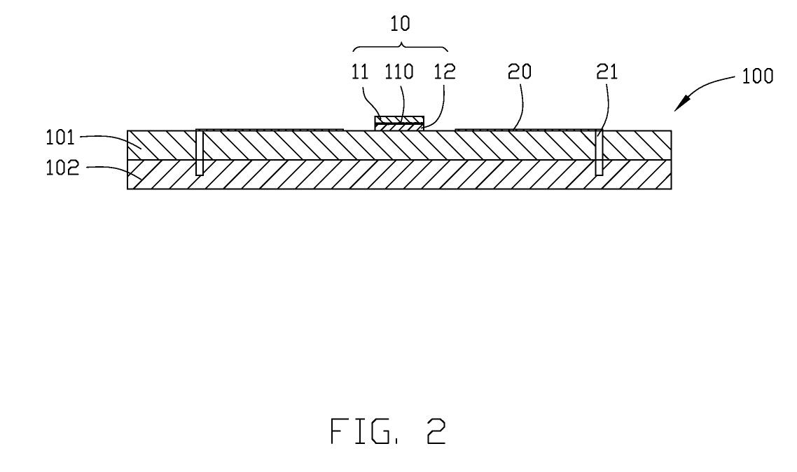

Referring to FIG. 1 and FIG. 2, an exemplary embodiment of a printed circuit board (PCB) 100 is applied in a portable electronic device, such as a notebook computer or a mobile phone. The PCB 100 includes a signal layer 101 and a ground layer 102. The signal layer 101 includes a switch 10 and two grounding copper foils 20. In another exemplary embodiment, the signal layer 101 may include more than two grounding copper foils 20.

The switch 10 includes an electroplated button 11 and a switch component 12. The switch component 12 is formed on the PCB 100 and under the electroplated button 11. The switch component 12 may be a single-pole double-throw (SPDT) switch. The two grounding copper foils 20 are respectively formed at opposite sides of the switch component 12.

A first end of each of the grounding copper foils 20 is adjacent to the switch 10. A second end of each of the grounding copper foils 20 is connected to the ground layer 102 of the PCB 100 via a via 21. A width of each of the grounding copper foils 20 is equal to or greater than about 1 millimeter (mm). A length of each of the grounding copper foils 20 is equal to or greater than about 10 mm. It may be understood that the values mentioned above may be changed depending on the embodiment.

An inner surface of the electroplated button 11 connected to the switch component 12 is coated with lacquer 110 mixed with insulative material. In use, when the electroplated button 11 of the switch 10 is pressed by an operator, any electrostatic charge of the operator's body may be released through electrostatic discharge (ESD) via contacting the electroplated button 11. The lacquer 110 coated on the inner surface of the electroplated button 11 prevents electrostatic current of the operator's body from effecting the switch component 12 directly, and guides the electrostatic current to the copper foils 20 and so to ground, thereby protecting the switch component 12 and the PCB 100.

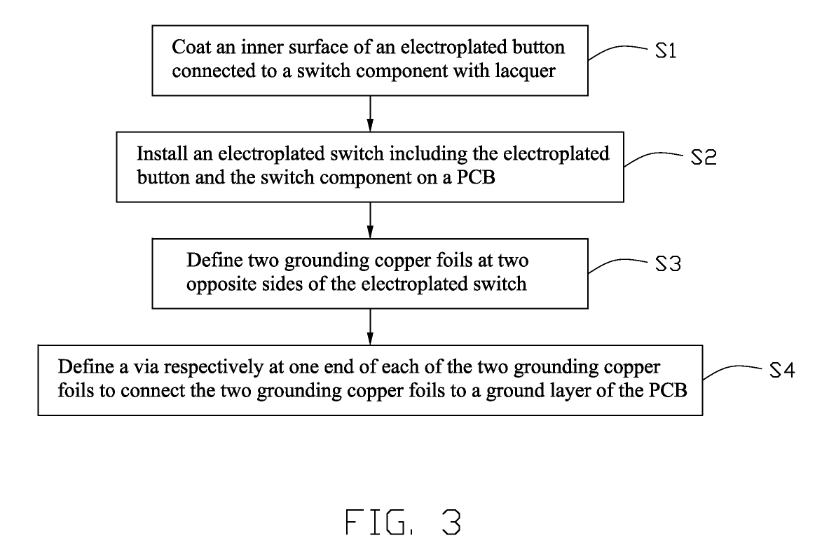

Referring to FIG. 3, a method of electrostatic discharge (ESD) protection method for the PCB 100 of FIG. 1 is provided, which includes the following steps.

Step S1: the inner surface of the electroplated button 11 connected to the switch component 12 is coated with lacquer 110.

Step S2: the switch 10 including the electroplated button 11 and the switch component 12 is installed on the PCB 100.

Step S3: two grounding copper foils 20 are respectively formed on the PCB 100 at opposite sides of the switch 10, where a first end of each of the grounding copper foils 20 is adjacent to the switch 10.

Step S4: a via 21 is respectively defined in the PCB 100 to connect a second end of each of the grounding copper foils 20 to connect the grounding copper foil 20 to the ground layer 102 of the PCB 100.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A printed circuit board (PCB), comprising:
a ground layer, and
a signal layer comprising:
a switch comprising:
a switch component formed on the signal layer; and
an electroplated button with an inner surface connected to the switch component and coated with lacquer; and
a plurality of grounding copper foils respectively formed on the signal layer and at opposite sides of the switch; wherein a first end of each of the grounding copper foils is formed on the signal layer and adjacent to the switch component, the plurality of grounding copper foils are also connected to the ground layer.

2. The PCB of claim 1, wherein the lacquer is made of insulative material

3. The PCB of claim 1, wherein the signal layer comprises two grounding copper foils at opposite sides of the switch, respectively.

4. The PCB of claim 1, wherein a width of each of the grounding copper foils is equal to or greater than about 1 millimeter.

5. The PCB of claim 1, wherein a length of each of the plurality of grounding copper foils is equal to or greater than about 10 millimeters.

6. The PCB of claim 1, wherein a second end of each of the plurality of grounding copper foils is connected to the ground layer via a via.

7. An electrostatic discharge (ESD) protection method for preventing a printed circuit board (PCB) from damage by ESD, the PCB comprising a ground layer and a signal layer, the signal layer comprising a switch, the switch comprising an electroplated button and a switch component under the electroplated button, the method comprising:
coating an inner surface connected to the switch component of the electroplated button with lacquer; and
providing a plurality of grounding copper foils at opposite sides of the switch; wherein a first end of each of the plurality of grounding copper foils is formed on the signal layer and adjacent to the switch component, the plurality of grounding copper foils are also connected to the ground layer.

8. The method of claim 7, further comprising defining a via in the signal layer to connect a second end of each of the grounding copper foils to the ground layer.

9. The method of claim 7, wherein the lacquer is made of insulation material.

10. The method of claim 7, wherein the signal layer comprises two grounding copper foils at opposite sides of the switch.

11. The method of claim 7, wherein a width of each of the plurality of grounding copper foils is equal to or greater than about 1 millimeter.

12. The method of claim 7, wherein a length of each of the plurality of grounding copper foils is equal to or greater than about 10 millimeters.
